(19) United States
(12) Patent Application Publication
(10) Pub. No.: US 2015/0263195 A1
(43) Pub. Date: Sep. 17, 2015

(54) SOLAR CELL AND METHOD OF FABRICATING SAME

(71) Applicant: TSMC Solar Ltd., Taichung City (TW)

(72) Inventor: Chien-Yao HUANG, New Taipei City (TW)

(73) Assignee: TSMC Solar Ltd., Taichung City (TW)

(21) Appl. No.: 14/210,493

(22) Filed: Mar. 14, 2014

(51) Int. Cl. H01L 31/0224; H01L 31/18

(52) U.S. Cl. CPC H01L 31/022441; H01L 31/18

(57) ABSTRACT

A solar cell and a method of fabricating the solar cell is described. The solar cell includes a substrate, a back contact layer over the substrate, a P1 trench on an upper portion of the back contact layer, and an insulator disposed in the P1 trench. The solar cell can also include an absorber layer over the back contact layer and insulator and a front contact layer over the absorber layer.

### BACKGROUND

This disclosure relates to fabrication of photovoltaic solar cells.

Solar cells are electrical devices for direct generation of electrical current from sunlight via the photovoltaic effect. A plurality of solar cells are connected in series by respective interconnect structures to form a solar cell module. The solar cells can be connected via monolithic integration. During this process, trenches for interconnect structures are scribed in the solar cell materials to isolate and connect the solar cells. However, monolithic integration of solar cells results in a loss in conversion efficiency due to series resistance, shunting paths, and dead areas in the devices.

There is a trade-off between shunting path loss and dead area loss in solar cell devices. In particular, shunting path loss generally decreases with the width of an interconnect structure, while dead area loss generally increases with the width of the interconnect structure. This trade-off limits the efficiency of the devices because methods to improve the shunting path loss often worsen the dead area loss and vice versa.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic cross section of a solar cell, in accordance with some embodiments.

FIG. 2A is a schematic cross section of solar cell substructure, in accordance with some embodiments.

FIG. 2B is a schematic cross section of solar cell substructure, in accordance with some embodiments.

FIG. 2C is a schematic cross section of solar cell substructure, in accordance with some embodiments.

FIG. 3 is a schematic cross section of a solar cell, in accordance with some embodiments.

FIG. 4 is a flow chart of a method of fabricating a solar cell, in accordance with some embodiments.

FIG. 5A is a schematic cross section of a solar cell substructure, in accordance with some embodiments.

FIG. 5B is a schematic cross section of a solar cell substructure, in accordance with some embodiments.

FIG. 5C is a schematic cross section of a solar cell substructure, in accordance with some embodiments.

FIG. 5D is a schematic cross section of a solar cell substructure, in accordance with some embodiments.

FIG. 5E is a schematic cross section of a solar cell substructure, in accordance with some embodiments.

FIG. 5F is a schematic cross section of a solar cell substructure, in accordance with some embodiments.

FIG. 5G is a schematic cross section of a solar cell substructure, in accordance with some embodiments.

FIG. 6 is a chart of simulated efficiency versus P1 width for a solar cell in accordance with some embodiments compares with other solar cell devices.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Although particular examples of solar cells are described below, the structures and methods described herein can be applied to a broad variety of solar cells, including Cu(In,Ga)Se₂ (CIGS), CuInSe₂ (CIS), CuGaSe₂ (CGS), Cu(In,Ga)(Se,S)₂ (CIGSS), amorphous silicon (α-Si), and cadmium telluride (CdTe) with pn junction, p-i-n stricture, MIS structure, multi-junction, or the like.

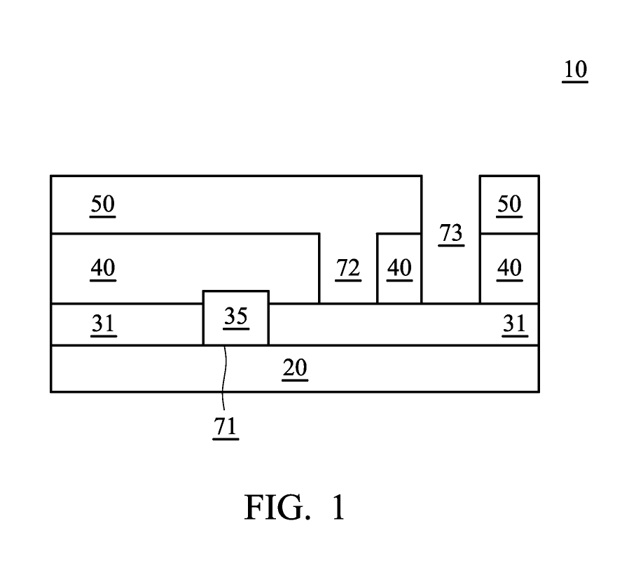

FIGS. 1-3 show solar cells 10 and substructures according to some embodiments of the disclosure. As shown in FIG. 1, the solar cell 10 includes a substrate 20 and a back contact layer 31 over the substrate 20, an insulator 35 over the substrate 20, an absorber layer 40 over the back contact layer 31, and a front contact layer 50 over the absorber layer 40. The insulator 35 can be embedded within the solar cell 10 below the front contact layer 50 and, in some embodiments, below at least a portion of the absorber layer 40.

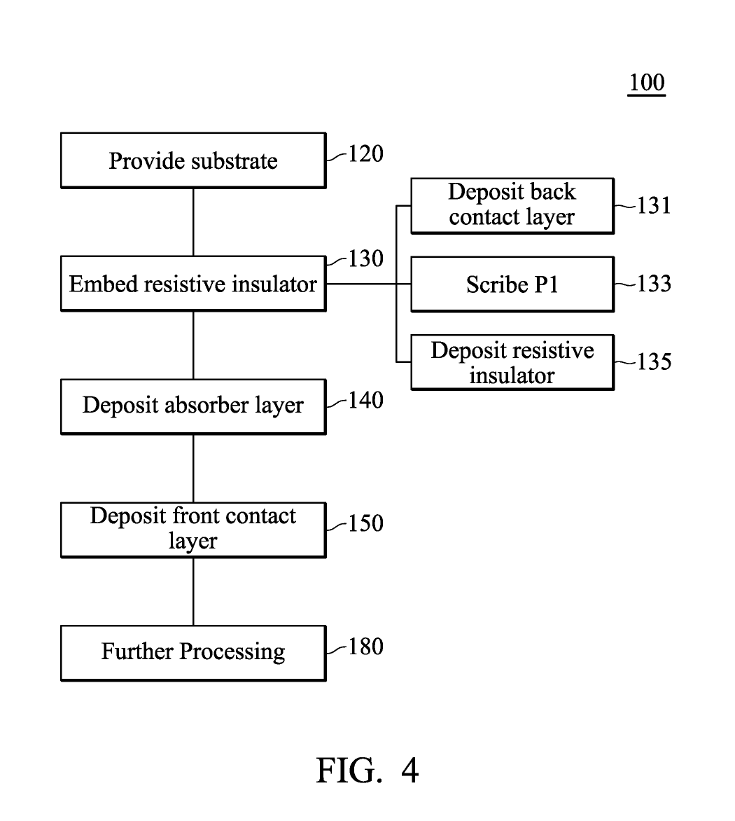

FIG. 4 shows a flowchart describing a broad method 100 for fabricating a solar cell. At step 120, the substrate is provided. The substrate 20 includes any suitable substrate material. In some embodiments, the substrate 20 can include glass (e.g., soda lime glass or sodium-free (high strain point) glass), flexible metal foil (e.g., stainless foil), a polymer (e.g., polyimide, polyethylene terephthalate (PET), polyethylene naphthalene (PEN)), or other suitable substrate materials. In some embodiments, the thickness of the substrate 20 can range from about 50 nm to about 2 μm.

At step 130, the insulator is embedded in the back contact layer over the substrate. In some embodiments, the “insulator” comprises an insulator material that has a resistivity greater than the resistivity of the absorber layer 40. In some embodiments, the insulator can have a resistivity of about 10,000 ohm-cm or greater. For example, the insulator can have a resistivity of greater than 10,000 ohm-cm or greater; or about 10,500 ohm-cm or greater; 11,000 ohm-cm or greater; 12,500 ohm-cm or greater; or 15,000 ohm-cm or greater. In some embodiments, the insulator 35 includes a silicon oxide (SiOₓ) such as SiO₂, a silicon nitride the like. In some embodiments, the insulator 35 is deposited, formed or otherwise disposed through at least a portion of the back contact layer 31 such that the back contact layer material surrounds at least a portion of the sides of the insulator 35. In some embodiments, the insulator 35 extends through the entire thickness of the back contact layer 31 as shown in FIG. 1.

In some embodiments, the insulator 35 can be embedded in the back contact layer 31 according to substeps 131-135 as shown in FIG. 4. At substep 131, the back contact layer 31 is deposited over the substrate 20. The back contact layer 30 includes any suitable conductive material, such as metals. In some embodiments, the back contact layer 30 can include molybdenum (Mo), platinum (Pt), gold (Au), silver (Ag), nickel (Ni), or copper (Cu). The back contact layer 30 can be selected based on the type of thin film solar cell device. For example, in a CIGS or other CIS-based solar device 10, back contact layer 30 can be Mo In some embodiments, the thickness of the back contact layer 30 can range from about 50 nm to about 2 μm.

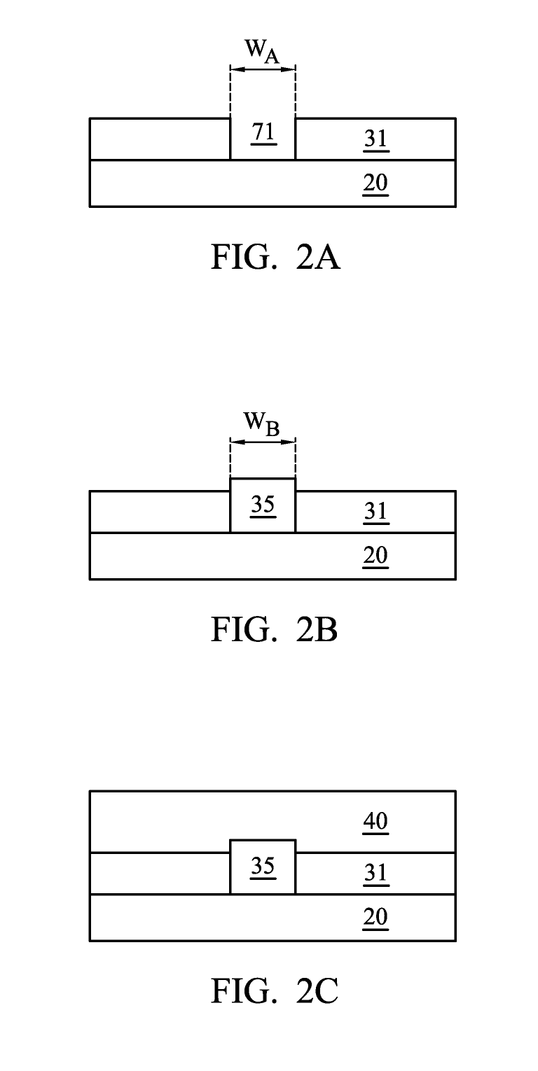

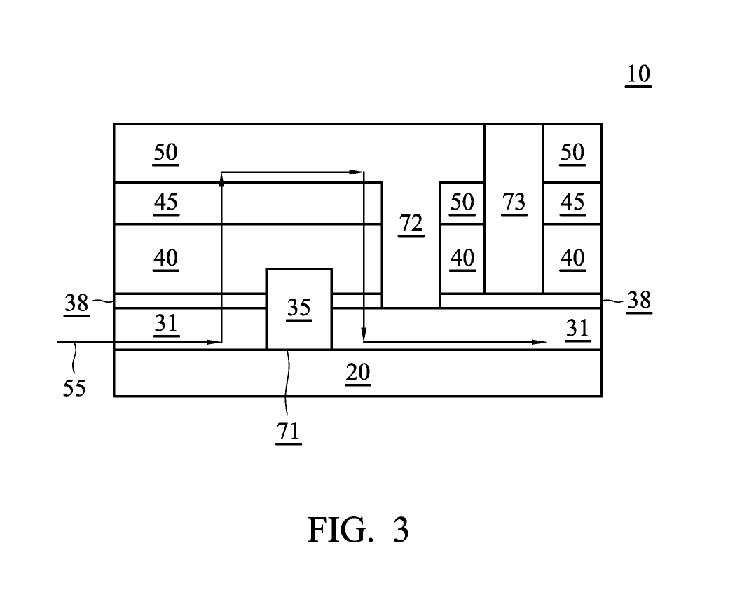

At substep 133, a P1 trench 71 is scribed in the back contact layer 31. The trench 71 can extend through the entire thickness of the back contact layer 31 as shown in FIG. 2A, or can extend through only a portion of the thickness of the back contact layer 31. In some embodiments, the solar cell 10 also includes an interface layer 38 formed between the back contact layer 31 and absorber layer 40 as shown in FIG. 3. The interface layer 38 includes corresponding materials, such as a molybdenum diselenide (MoSe₂) interface layer 38 for a Mo back contact layer 31. In embodiments with an interface layer 38, the P1 trench 71 is can also be scribed through the interface layer 38.

The P1 trench 71 can be scribed using laser scribing, mechanical patterning, photolithography, or other suitable methods. In some embodiments, the P1 trench 71 can have a width (demonstrated in FIG. 2A as W_{A}) of less than about 50 μm or less. In other embodiments, the width W_{A} of the trench 71 can be about 30 μm or less or 25 μm or less. Preferably, the width W_{A} can be less than 25 μm. For example, the width W_{A} of the trench 71 can be about 20 μm or less, or 15 μm or less, 15 μm or less, 10 μm or less, or 5 μm or less.

At substep 135, the insulator 35 is deposited within the P1 trench 71. In some embodiments, the deposition is performed by, for example, physical vapor deposition (PVD), chemical vapor deposition (CVD), atomic layer deposition (ALD) or the like. The insulator can have a width (shown in FIG. 2B as W_{B}) sized to fit within the P1 trench 71. For example, the width W_{B} can be substantially equal to the trench width W_{A}. In some embodiments, the insulator 35 can substantially fill the P1 trench 71 as shown in FIG. 2B or the insulator 35 can fill only a portion of the P1 trench 71. In some embodiments, the insulator 35 has a thickness greater than a thickness of the back contact layer 31. In some embodiments, the insulator 35 has a thickness less than the thickness of the absorber layer 40 or less than the combined thickness of the back contact layer 31 and absorber layer 40. The insulator 35 can also be sized according to any combination of the foregoing. For example, the insulator 35 can have a thickness ranging between the thickness of the back contact layer 31 and the thickness of the absorber layer 40. In another example, the insulator 35 can have a thickness greater than the back contact layer 40 and a width W_{B} substantially equal to the trench width W_{A}.

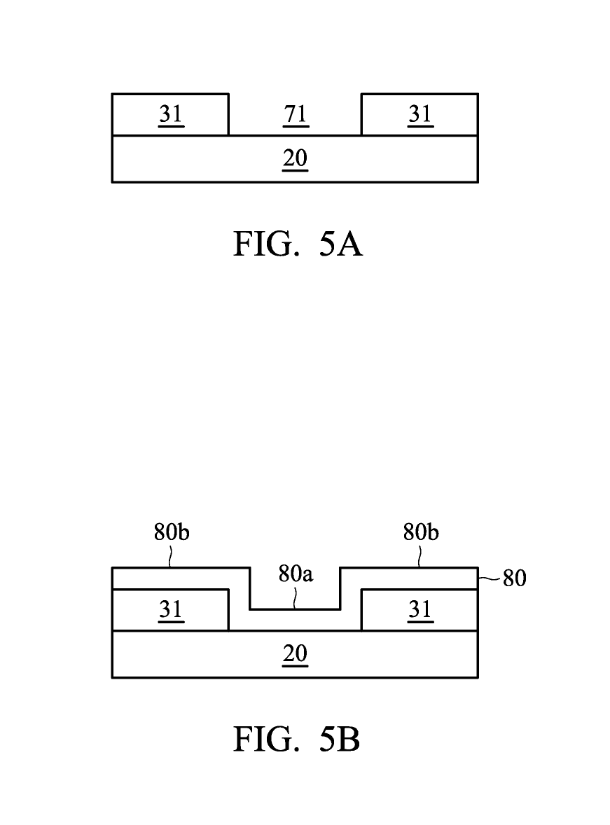

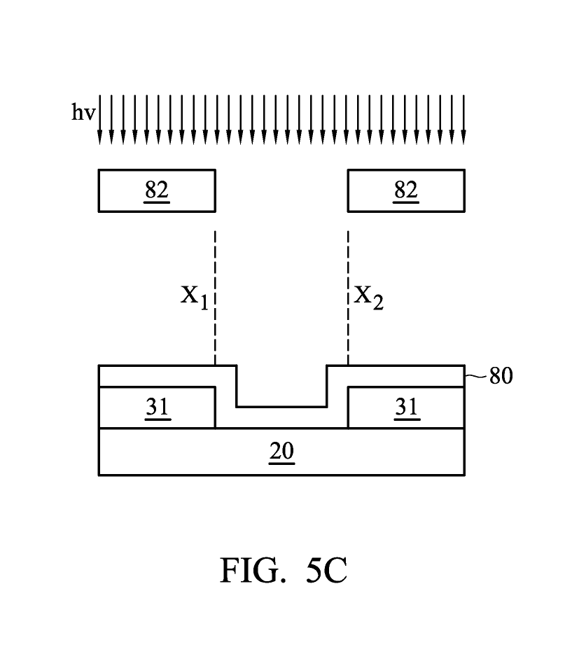

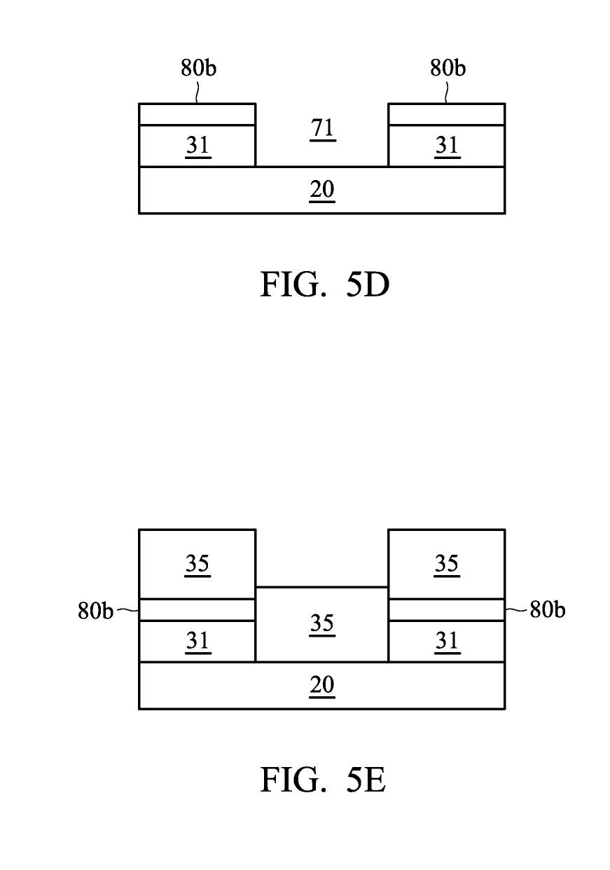

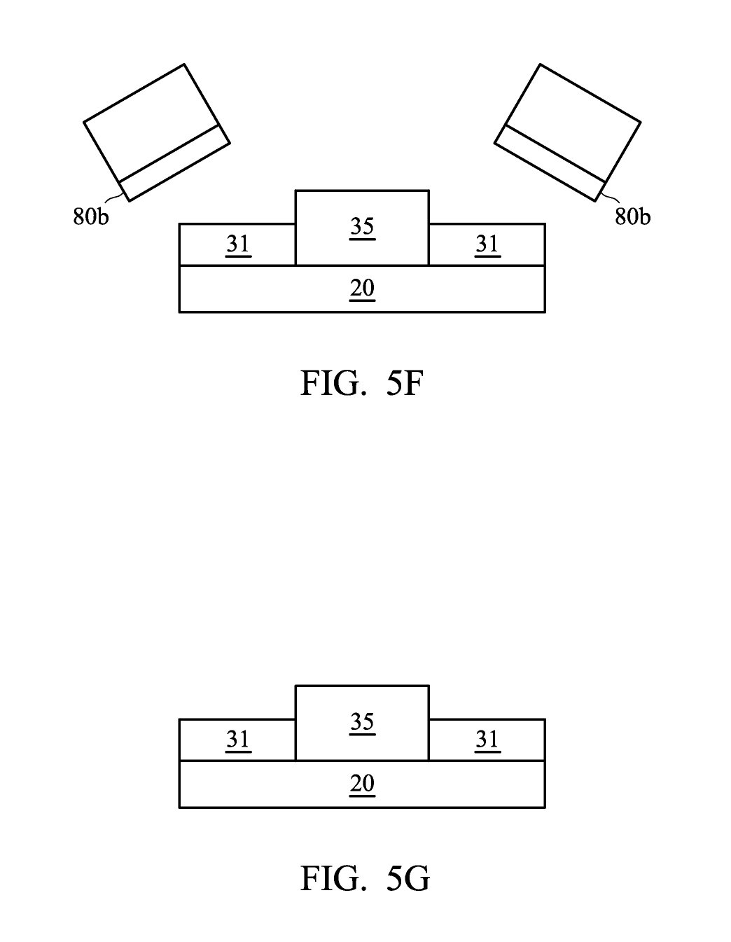

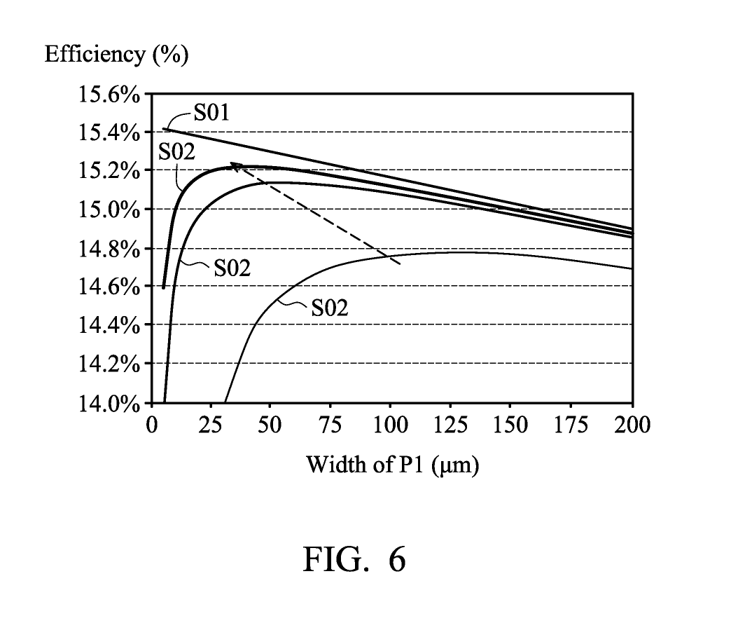

In other embodiments, the substeps can also include the application of a photo-resist to the solar cell substructure. For example, a resist material can be deposited over the substructure shown in FIG. 5A comprising the back contact layer 31 over the substrate 20 and a P1 trench 71 scribed through the back contact layer to form a resist layer over the substructure as shown in FIG. 5B. The resist layer 80 can include a P1 trench portion 80a (i.e., portion of resist layer 80 lining the P1 trench 71) and a remaining portion 80b (i.e., the remaining portion of the deposited resist layer 80 over the rest of the back contact layer 31). A shadow mask 82 can be applied to expose the P1 trench 71 (the boundaries of the scribed trench 71 are shown as lines X₁ and X₂ in FIG. 5C) and the P1 trench portion 80a of the resist layer 80 can be dissolved as shown in FIG. 5C, resulting in the substructure shown in FIG. 5D. The insulator 35 can then be deposited or formed within the P1 trench 71 as shown in FIG. 5E, and the remaining portion 80b of the resist layer 80 can be dissolved as shown in FIG. 6F, resulting in the substructure shown in FIG. 5G.

In other embodiments, the insulator 35 can be embedded in the back contact layer 31 using different techniques at step 130. For example, the insulator 35 can be deposited or formed over the substrate 20, then the back contact layer 31 can be deposited on the substrate and around the insulator 35.

At step 140, the absorber layer is deposited over the back contact layer 31 and the insulator 35. In embodiments where the insulator 35 has a thickness greater than the back contact layer 31, the insulator 35 can extend through at least a portion of the absorber layer 40. In some embodiments, the absorber layer material covers the upper surface of the insulator 35 and at least a portion of the sides of the insulator 35, as shown in FIG. 2C.

The absorber layer 40 includes any suitable absorber material, such as p-type semiconductors. In some embodiments, the absorber layer 40 comprises chalcopyrite-based material and can be CIGS, CIGSS, CIS, or CGS. The absorber layer 40 can be formed over the substrate 20 and back contact layer 30 according to methods such as sputtering, chemical vapor deposition, electrodeposition or the like. For example, a CIGS absorber layer can be formed by depositing metal precursors for copper, indium and gallium, followed by a selenization process including introducing selenium or selenium-containing chemicals in a gas state into the metal layers. In some embodiments, the selenium is introduced by evaporation. A sulfurization process introducing sulfur or sulfur-containing chemicals in a gas state to the CIGS layer can also be applied. In some embodiments, the thickness of the absorber layer 40 can range from about 0.3 μm to about 10 μm.

In some embodiments, a buffer layer 45 is deposited on the absorber layer 40 by chemical deposition (e.g., chemical bath deposition), PVD, ALD, or other suitable techniques. Buffer layer 45 includes any suitable buffer material, such as n-type semiconductors. In some embodiments, buffer layer 45 can include cadmium sulfide (CdS), zinc sulphide (ZnS), zinc selenide (ZnSe), indium(III) sulfide (In₂S₃), indium selenide (In₂Se₃), or Zn₁₋ₓMgₓO, (e.g., ZnO). Other embodiments include still other buffer materials. In some embodiments, the buffer layer 45 is from about 1 nm to about 500 nm thick. After forming the buffer layer 45 (or after forming the absorber 40, if no buffer layer is included), the P2 scribe line is formed through the buffer layer and absorber layer 40.

At step 150, the front contact layer 50 is deposited over the absorber layer 40. In some embodiments, the front contact 50 is deposited by metal organic chemical vapor deposition (MOCVD). In other embodiments, the front contact is deposited by sputtering or ALD. The front contact layer 50 includes suitable front contact layer materials, such as metal oxides (e.g. indium oxide). In some embodiments, the front contact layer includes transparent conductive oxides such as indium tin oxide (ITO), fluorine-doped tin oxide (FTO), aluminum-doped zinc oxide (AZO), gallium doped ZnO (GZO), alumina and gallium co-doped ZnO (AGZO), boron-doped ZnO (BZO), and combinations thereof. After forming the front contact layer 50, the P3 scribe line is formed through the front contact 50, buffer layer 45 and absorber layer 40.

In some embodiments at step 180, the solar cell can undergo additional processing operations to complete the device and/or connect the device to other solar cells to form solar modules. For example, further processing may include EVA/butyl applications, lamination, back end processing, and module formation. Solar modules can, in turn, be coupled to other solar modules in series or in parallel to form arrays.

FIG. 6 is a chart showing simulated device efficiency relative to P1 width for a CIGS solar cell according to the disclosure (S01) and a CIGS solar cell (S02) without the insulator 35. For the S02 devices, the results show an optimized P1 width with different resistivities for the absorber, which are shown as three curved lines (S02) in FIG. 6. The data shows that S02 devices with higher resistivity absorbers have a higher optimized conversion efficiency. The results also demonstrate that the S01 devices realize an overall higher conversion efficiency than the S02 devices, which are limited to an optimized S02 efficiency at a P1 width between about 25-100 μm. In contrast, the S01 devices minimize both the dead area loss while maximizing the benefits of a smaller P1 width, leading to a significant improvement in efficiency. In some embodiments, the solar cell 10 can realize a conversion efficiency of 15.2% or greater, 15.3% or greater, and 15.4% or greater.

The solar cells, solar cell substructures and methods according to the disclosure provide improved solar cell performance. In particular, the device effectively breaks the trade-off between shunting path loss and dead areas loss from P1 width, providing an open circuit and blocking shunting paths across the P1 interconnect. As shown in FIG. 3, the current 55 flows around the insulator 35, eliminating shunts in the P1 scribe line. Thus, shunting loss is significantly reduced or prevented while at the same time the dead area loss is minimized by narrowing the width of the P1 interconnect. In summary, the solar cells, substructures and methods for fabricating solar cells disclosed herein boosts solar module efficiency and the efficient and effective methods can be easily implemented in existing solar cell fabrication processes. For example, the methods are easy to integrate with current CIGS production lines. As such, the disclosed methods can provide significantly improved devices at a low additional cost.

In some embodiments, a solar cell substructure includes a substrate; a back contact layer over the substrate; a P1 trench in the back contact layer; and an insulator disposed in the P1 trench.

In some embodiments, the P1 trench has a width of less than about 30 μm.

In some embodiments, the P1 trench has a width of about 25 μm or less.

In some embodiments, the insulator fills the P1 trench.

In some embodiments, the insulator has a width substantially equal to the width of the P1 trench.

In some embodiments, the insulator has a thickness greater than a thickness of the back contact layer.

In some embodiments, the solar cell substructure also includes an absorber layer over the back contact layer, and the insulator has a thickness less than a combined thickness of the back contact layer and the absorber layer.

In some embodiments, a solar cell includes a substrate; a back contact layer over the substrate; an insulator over the substrate and extending through the back contact layer; an absorber layer over the back contact layer and the insulator; and a front contact layer over the absorber layer.

In some embodiments, the insulator extends through a portion of the absorber layer.

In some embodiments, the insulator has a thickness less than a combined thickness of the back contact layer and absorber layer.

In some embodiments, the insulator has a resistivity of about 10,000 ohm-cm or greater.

In some embodiments, the insulator has a resistivity of about 15,000 ohm-cm or greater.

In some embodiments, the insulator includes silicon dioxide.

In some embodiments, the P1 trench has a width of less than 25 μm

In some embodiments, the absorber layer includes chalcopyrite-based materials.

In some embodiments, a method for fabricating a solar cell includes providing a substrate; providing a back contact layer over the substrate with an insulator embedded therein; depositing an absorber layer over the back contact layer and insulator; and depositing a front contact layer over the absorber layer.

In some embodiments, the step of providing the back contact layer includes depositing the back contact layer over the substrate, scribing a P1 trench through the back contact layer and forming the insulator in the P1 trench.

In some embodiments, the step of providing the back contact layer includes depositing the back contact layer over the substrate, depositing a resist layer over the back contact layer, the resist layer including a P1 trench portion and a remaining portion; exposing the P1 trench with a shadow mask; dissolving the P1 trench portion of the resist layer; depositing the insulator within the P1 trench; and dissolving the remaining portion of the resist layer.

In some embodiments, the embedding step is performed prior to the absorber layer depositing step.

In some embodiments, the absorber layer depositing step includes precursor deposition and selenization.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A solar cell substructure comprising:
a substrate;
a back contact layer over said substrate;
a P1 trench in said back contact layer; and
an insulator disposed in said P1 trench.

2. The solar cell as in claim 1, wherein said P1 trench has a width of less than about 30 μm.

3. The solar cell as in claim 1, wherein said P1 trench has a width of about 25 μm or less.

4. The solar cell as in claim 1, wherein said insulator fills said P1 trench.

5. The solar cell as in claim 1, wherein said insulator has a width substantially equal to the width of the P1 trench.

6. The solar cell as in claim 1, wherein said insulator has a thickness greater than a thickness of the back contact layer.

7. The solar cell as in claim 1, further comprising an absorber layer over said back contact layer, wherein said insulator has a thickness less than a combined thickness of said back contact layer and said absorber layer.

8. A solar cell comprising:
a substrate;
a back contact layer over said substrate;
an insulator over said substrate and extending through said back contact layer;
an absorber layer over said back contact layer and said insulator; and
a front contact layer over said absorber layer.

9. The solar cell as in claim 8, wherein said insulator extends through a portion of said absorber layer.

10. The solar cell as in claim 8, wherein said insulator has a thickness less than a combined thickness of said back contact layer and absorber layer.

11. The solar cell as in claim 8, wherein said insulator has a resistivity of about 10,000 ohm-cm or greater.

12. The solar cell as in claim 8, wherein said insulator has a resistivity of about 15,000 ohm-cm or greater.

13. The solar cell as in claim 8, wherein said insulator comprises silicon dioxide.

14. The solar cell as in claim 8, wherein said P1 trench has a width of less than 25 μm.

15. The solar cell as in claim 8, wherein said absorber layer comprises chalcopyrite-based materials.

16. A method for fabricating a solar cell, comprising:
providing a substrate;
providing a back contact layer over said substrate with an insulator embedded therein;
depositing an absorber layer over said back contact layer and insulator; and
depositing a front contact layer over said absorber layer.

17. The method as in claim 16, wherein said step of providing said back contact layer comprises:
depositing said back contact layer over said substrate;
scribing a P1 trench through said back contact layer;
and forming said insulator within said P1 trench.

18. The method as in claim 16, wherein said step of providing said back contact layer comprises:
depositing said back contact layer on said substrate;
depositing a resist layer on said back contact layer, said resist layer comprising a P1 trench portion and a remaining portion;
exposing said P1 trench with a shadow mask;
dissolving said P1 trench portion of said resist layer;
depositing said insulator within said P1 trench; and
dissolving said remaining portion of said resist layer.

19. The method as in claim 16, wherein said embedding step is performed prior to said absorber layer depositing step.

20. The method as in claim 16, wherein said absorber layer depositing step comprises precursor deposition and selenization.
